(19) United States
(12) Patent Application Publication
(10) Pub. No.: US 2023/0349044 A1
(43) Pub. Date: Nov. 2, 2023

(54) WORKPIECE HOLDER, SYSTEM, AND OPERATING METHOD FOR PECVD

(71) Applicant: centrotherm international AG, Blaubeuren (DE)

(72) Inventors: Jens-Uwe Fuchs, Blaubeuren (DE); Mirko Tröller, Blaubeuren (DE); Ralf Reize, Blaubeuren (DE); Roland Leichtle, Blaubeuren (DE)

(21) Appl. No.: 18/026,405

(22) PCT Filed: Sep. 14, 2021
(86) PCT No.: PCT/DE2021/100758

§ 371 Date: Mar. 15, 2023

(30) Foreign Application Priority Data
Sep. 15, 2020 (DE) 10 2020 124 022.8

(51) Int. Cl. C23C 16/458; C23C 16/509

(52) U.S. Cl. CPC C23C 16/4586; C23C 16/509

(57) ABSTRACT

A workpiece holder for a plasma-enhanced chemical vapor deposition system is configured to produce a plasma from a process gas surrounding the workpiece holder. The workpiece holder is also configured to heat the surroundings of the workpiece holder to a process temperature provided for the vapor deposition. A chemical vapor deposition system and an operating method for the system are also provided.

The present invention relates to a workpiece holder for a system for plasma-enhanced chemical vapor deposition, a system for plasma-enhanced chemical vapor deposition, and an operating method for a system for plasma-enhanced chemical vapor deposition.

The method of chemical vapor deposition (CVD) is known for coating substrates. At least one gas is provided, which contains the substance to be deposited. The substance is deposited on the substrate by running a chemical reaction, which is drivable by temperature, for example. With the aid of chemical vapor deposition, for example, microelectronic components or optical fibers can be produced.

The deposition rate may be increased further by exciting a plasma from the gas. Moreover, the deposition reaction can also already be effectively driven at lower temperatures in this way. This variant of chemical vapor deposition is typically referred to as plasma-enhanced chemical vapor deposition (PECVD).

To reach the required process temperature, workpiece holders for holding the substrates, for example semiconductor wafers, are typically inserted into a reaction chamber having heatable walls. Such reaction chambers are sometimes also referred to as hot wall reactors. The heating typically takes place via resistance heating elements, which are installed on or in the process chamber wall. Workpiece holders of the type described are often referred to as boats.

It is an object of the present invention to further improve plasma-enhanced chemical vapor deposition, in particular to increase its efficiency.

This object is achieved by a workpiece holder for a system for plasma-enhanced chemical vapor deposition, a system for plasma-enhanced chemical vapor deposition having such a workpiece holder, and an operating method for a system for plasma-enhanced chemical vapor deposition according to the independent claims.

Advantageous refinements are the subject matter of respective dependent subclaims.

A workpiece holder according to a first aspect of the invention for a system for plasma-enhanced chemical vapor deposition is configured to generate a plasma from a process gas surrounding the workpiece holder. According to the invention, the workpiece holder is also configured to heat the surroundings of the workpiece holder to a process temperature provided for vapor deposition.

One aspect of the invention is based on the approach of setting a provided process temperature for depositing at least one substance from a gas phase, preferably exclusively, by means of a workpiece holder. The workpiece holder is expediently configured here to heat the surroundings of the workpiece holder, for example a process gas surrounding the workpiece holder and/or a workpiece held by the workpiece holder, to the process temperature. The workpiece holder can in particular have heating elements, for example in the form of multiple heating resistors, and can thus be configured to be operated as a heating unit. Thus, for example, a separate heating system arranged in the area of the process chamber for a process chamber of a PECVD facility, for example in the form of heating elements or a heating cartridge, may be omitted. The PECVD facility can thus be designed more simply and, for example, produced more cost-effectively.

In addition, installation space can be saved and as a result the PECVD facility can be designed smaller due to the operation of the workpiece holder as a heating unit in the process chamber. As a result, the volume to be heated and the mass to be heated may be reduced. This enables shortening of the time required to reach the process temperature at equal heating power. The throughput through a corresponding PECVD facility may thus in turn be increased.

The workpiece holder is preferably also configured here, in addition to heating its surroundings, to generate a plasma from the process gas surrounding the workpiece holder. The concept of process gas within the meaning of the present invention is also to be understood as a mixture of various process gases. For the mentioned purpose, the workpiece holder can have an electrode assembly, for example in the form of multiple electrodes arranged in parallel, to which a high-frequency electric AC voltage can be applied. For plasma generation, the polarity of the electrodes can be changed at a frequency of 1 kHz or more, for example at approximately 40 kHz. The workpiece holder is particularly preferably configured to heat its surroundings with the aid of the electrode assembly, i.e., with the aid of the multiple electrodes.

The workpiece holder can therefore advantageously be configured to generate the plasma and to heat its surroundings using only one component, namely using the electrode assembly, for example. This enables particularly efficient use of the components or assemblies of the workpiece holder.

For example, the workpiece holder can be configured in a first operating mode to generate the plasma from the process gas, preferably upon an application of the high-frequency electric AC voltage to the workpiece holder. The high-frequency electric AC voltage can in particular be applied to the multiple electrodes for this purpose. In addition, the workpiece holder can be configured in a second operating mode to heat its surroundings to the process temperature, preferably upon an application of a low-frequency AC voltage to the workpiece holder. In this case, the polarity of the multiple electrodes can be changed at less than 1 kHz, for example at 50 Hz.

Preferred embodiments of the invention and refinements thereof are described hereinafter and, in so far as this is not expressly precluded, can each be combined as desired with one another and with the aspects of the invention described hereinafter.

In one preferred embodiment, the workpiece holder, in particular the electrode assembly, is configured to conduct electric heating current. A heating current is in this case preferably an electric alternating current at a frequency of less than 1 kHz, for example at 50 Hz. In a preferred manner, a heating current has an effective amperage of 90 A or more, for example of 120 A. The workpiece holder expediently comprises at least one heating circuit for this purpose. The heating circuit can comprise, for example, at least a part of the electrode assembly, i.e., can be formed at least partially from at least a part of the electrode assembly. In particular, the at least one heating circuit can include a group of electrodes from the electrodes of the electrode assembly. Heating of the surroundings of the workpiece holder can thus be precisely controlled.

For example, the electrode assembly of the workpiece holder can be designed in such a way that upon the application of a low-frequency AC voltage of 145 V (effective voltage) to the workpiece holder, an electric alternating current flows as a heating current through the electrode assembly. In particular, the multiple electrodes of the electrode assembly can be interconnected in such a way that by applying the low-frequency AC voltage, heating of the electrodes takes place without a plasma being ignited at the same time. The electrode assembly may thus be used not only in a conventional manner for plasma generation, but rather also to reach the process temperature. The electrode assembly may thus be used particularly efficiently and the workpiece holder may be implemented with particularly few components—and thus cost-effectively.

Conventional workpiece holders, in contrast, are not suitable for conducting heating current. A low-frequency alternating current flowing there through an electrode assembly, for example, would not cause heating of the electrodes, since the electrodes would merely act as a reactance.

In a further preferred embodiment, the workpiece holder is configured to conduct, in particular in parallel, electric alternating current in multiple circuits. In other words, the workpiece holder has multiple, i.e., at least two circuits. The circuits are expediently separated from one another. Each of the circuits can form a separately actuatable heating circuit here. The circuits can therefore also be referred to as a heating circuit. The circuits are preferably formed at least partially by at least a part of the electrode assembly, preferably by different groups of electrodes. The circuits are expediently designed as connectable for connecting the workpiece holder to a power supply, for example to a corresponding plug arrangement in the form of contact pins of a PECVD facility. Due to the conduction of alternating current in multiple circuits, the voltages or currents required to reach the process temperature can be kept smaller. In addition to increasing the level of operational safety, the service life of the workpiece holder can thus also be lengthened. At the same time, homogeneous heating of the surroundings of the workpiece holder is thus achievable.

In a further preferred embodiment, the workpiece holder has multiple electrodes arranged in parallel, which are used as electric heating resistors. In other words, the electrodes of the electrode assembly can also form heating resistors designated as heating elements. The electrodes are expediently designed here to be connected to a heating voltage source and can be configured to distribute the provided low-frequency alternating current to the electrodes. The electrodes, for example in various operating modes of the workpiece holder, can thus be used both to generate a plasma and also to heat the workpiece.

The electrodes are preferably formed plate-shaped. Particularly uniform and/or large-area heat generation may thus be achieved.

In a further preferred embodiment, at least a part of the multiple electrodes is electrically connected in series.

The electric (overall) resistance required for effective heat generation is thus achievable more easily.

The electrodes can be connected in series in groups. In other words, multiple groups of electrodes can be provided, wherein all electrodes of one group are connected in series. Preferably, each of the groups forms at least one of multiple heating circuits of the workpiece holder, which are separated from one another. The electrodes can thus be used to generate the plasma in spite of an at least partial series connection, for example by applying a high-frequency AC voltage between electrodes from different groups.

The electrodes of one group are preferably arranged spatially separated from one another. The electrodes of one group are particularly preferably separated from one another by electrodes of another group. In other words, one electrode from the one group is preferably arranged adjacent to the electrodes from the other group; it is particularly preferably arranged exclusively adjacent to electrodes from the other group.

In a further preferred embodiment, adjacent ones of the multiple electrodes are electrically isolated from one another. In other words, no electric connection exists between adjacent ones of the multiple electrodes. Adjacent electrodes can thus be set to different potentials. In particular, a high-frequency electric AC voltage can be applied to adjacent electrodes in such a way that a plasma is generated.

In a further preferred embodiment, the workpiece holder has a first distributor assembly arranged at a first end of the workpiece holder and a second distributor assembly arranged at a second end of the workpiece holder opposite to the first end. The distributor assemblies are preferably configured to distribute low-frequency and high-frequency electric AC voltage for heating the workpiece holder or for generating the plasma. A distribution of electric AC voltage is preferably in this case a conduction of AC voltage provided at the workpiece holder on multiple parallel heating circuits. For this purpose, the distributor assemblies can comprise, for example, a corresponding interconnection of the electrodes. The workpiece holder can be easily connected to a standardized power supply, for example, by the distributor assemblies. In particular, a workpiece holder having such distributor assemblies can also be used conventionally if needed, i.e., without heating of the workpiece by the workpiece holder.

In a further preferred embodiment, at least one of the two distributor assemblies connects at least a part of the multiple electrodes arranged in parallel in an electrically conductive manner. In particular, at least one of the two distributor assemblies can connect at least a part of the electrodes in the form of at least one series circuit. This facilitates the connection of the workpiece holder to a current and/or voltage supply.

In a further preferred embodiment, the workpiece holder has a power connection. The power connection preferably comprises at least four contact points for electrically contacting the workpiece holder. The contact points are preferably arranged spatially separated from one another, for example distributed over the width and/or height of the workpiece holder. The contact points can each be designed as connectable in pairs to the poles of an AC voltage source here. At least two heating circuits of the workpiece holder can thus be fed separately from one another reliably and safely.

The power connection is preferably arranged at a first end of the workpiece holder. The power connection is expediently part of the first distributor assembly. In particular, the power connection can be formed by the first distributor assembly. Due to the arrangement of the power connection at the first end of the workpiece holder, the workpiece holder can be incorporated particularly easily into one or more circuits, for example, upon insertion of the workpiece holder into a process chamber of a PECVD facility.

In a further preferred embodiment, the contact points have conical boreholes for receiving contact pins. The contact pins, which are sometimes also referred to as current lances, can be, for example, part of a PECVD facility and can be provided for electrically connecting the workpiece holder to the PECVD facility. The pins can slide easily into the boreholes via the cone shape here and can thus be guided to the respective provided position. This is advantageous in particular if the workpiece holder has some play upon the insertion into a process chamber of the PECVD facility and a precise alignment of the workpiece holder in relation to the pins cannot always be ensured.

A system according to a second aspect of the invention for plasma-enhanced chemical vapor deposition has a workpiece holder according to the first aspect of the invention. The system preferably moreover comprises a process chamber which can be charged with the process gas, and by which the workpiece holder can be received. Furthermore, the system preferably comprises at least one current and/or voltage source for the current or voltage supply of the workpiece holder. The system is particularly preferably configured here to heat the process chamber with the aid of the workpiece holder. For this purpose, the system can be configured to operate the workpiece holder received by the process chamber as a heating unit. Such a system can be designed particularly compactly and energy efficiently, in particular since a separate heating system does not have to be provided.

In one preferred embodiment, the system has a switching device, which is configured to first operate the workpiece holder as a heating unit to heat at least one workpiece held by the workpiece holder to a process temperature provided for vapor deposition and then as a plasma unit to generate a plasma from the process gas surrounding the workpiece holder. The switching device expediently comprises two switch assemblies each made up of at least one switch. In operation of the workpiece holder as a plasma unit, the at least one switch of a first of the two switch assemblies is preferably closed and the at least one switch of a second of the two switch assemblies is opened. Accordingly, in operation of the workpiece holder as a heating unit, the at least one switch of the first switch assembly is preferably open and the at least one switch of the second switch assembly is closed.

In a further preferred embodiment, the system has (i) a plasma voltage source for providing high-frequency electric AC voltage for operating the workpiece holder as a plasma unit and (ii) at least one heating voltage source for providing low-frequency electric AC voltage for operating the workpiece holder as a heating unit. The switching device is preferably configured here, after heating the workpiece to the process temperature, to disconnect the heating voltage source from the workpiece holder and to connect the plasma voltage source to the workpiece holder.

The switching device preferably has a control unit for this purpose. The control unit can be configured, for example, to open and close the two switch assemblies, in particular the switches of the switch assemblies. The control unit can be configured in particular, upon the presence of a switching signal, to disconnect the heating voltage source from the workpiece holder and to connect the plasma voltage source to the workpiece holder by appropriate actuation of the switch assemblies. The switching signal can be, for example, a switching signal generated by a user and provided via a user interface. Alternatively or additionally, the switching signal can also be generated by the control unit, for example, when a temperature of the workpiece holder or its surroundings reaches or exceeds the process temperature. For this purpose, the control unit can be connected to a temperature sensor, which is configured to determine or at least estimate the workpiece holder temperature or the ambient temperature.

In a further preferred embodiment, the switching device is configured to integrate the workpiece holder (i) into a plasma circuit during operation as a plasma unit and (ii) into at least one heating circuit during operation as a heating unit. For this purpose, the switch assembly is preferably configured to connect a first pole of the plasma voltage source to electrodes, which are part of the at least one heating circuit during operation of the workpiece holder as a heating unit. The switch assembly is preferably moreover configured to connect a second pole of the plasma voltage source to electrodes, which are not part of the first heating circuit, rather are preferably part of a second, separate heating circuit. The electrodes can thus be brought to two different potentials.

In an operating method according to a third aspect of the invention for a system for plasma-enhanced chemical vapor deposition, a workpiece holder is initially operated as a heating unit to heat at least one workpiece held by the workpiece holder to a process temperature provided for vapor deposition and then as a plasma unit to generate a plasma from a process gas surrounding the workpiece holder. In particular, a system according to the second aspect of the invention may advantageously be operated using this operating method.

During operation as a heating unit, a low-frequency AC voltage at less than 1 kHz, for example at 145 V (effective voltage), is preferably applied to the workpiece holder, so that an alternating current having an effective amperage of 90 A or more, in particular approximately 120 A flows. During operation as a plasma unit, a high-frequency AC voltage at 1 kHz or more, in particular approximately 40 kHz, for example at 800 V to 1000 V (effective voltage), is preferably applied to the workpiece holder, so that an alternating current having an effective amperage of less than 90 A, in particular approximately 75 A flows.

The invention is explained in more detail hereinafter on the basis of figures. If appropriate, identically acting elements are provided with identical reference signs herein. The invention is not restricted to the exemplary embodiments illustrated in the figures—also not with respect to functional features. The above description and also the following description of the figures contain numerous features which are sometimes reproduced in the dependent subclaims combined in multiples. These features and all other features disclosed above and in the following description of the figures will also be individually considered by a person skilled in the art and combined to form reasonable further combinations. In particular, all mentioned features are each combinable individually and in any suitable combination with the workpiece holder according to the first aspect of the invention, the system according to the second aspect of the invention, and the operating method according to the third aspect of the invention.

In the figures, which are at least partially schematic:

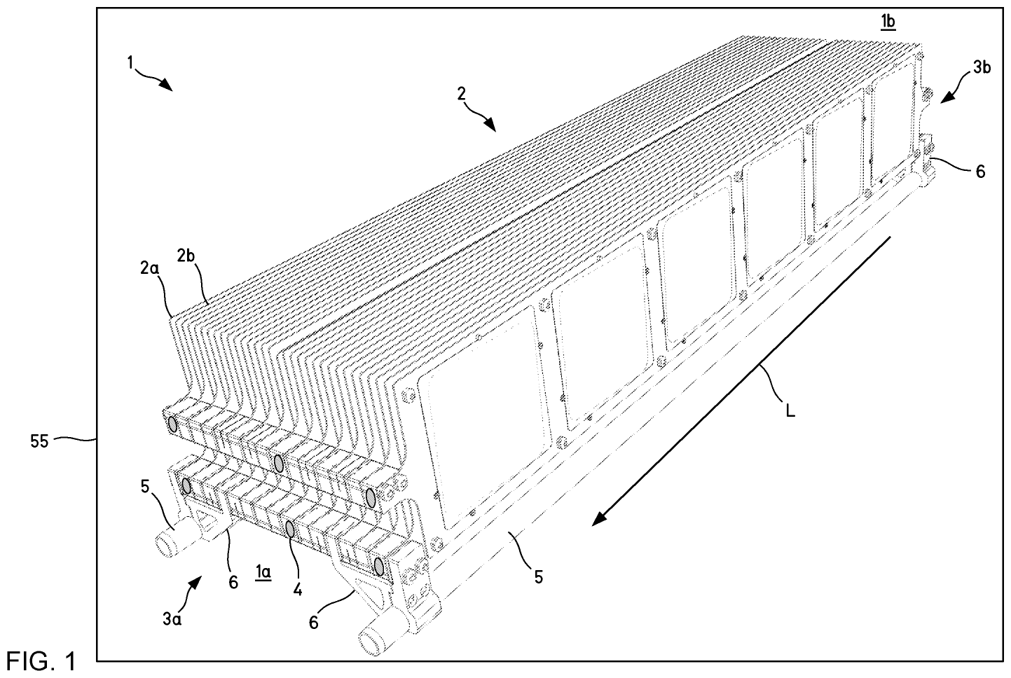

FIG. 1 shows an example of a workpiece holder for a system for plasma-enhanced chemical vapor deposition;

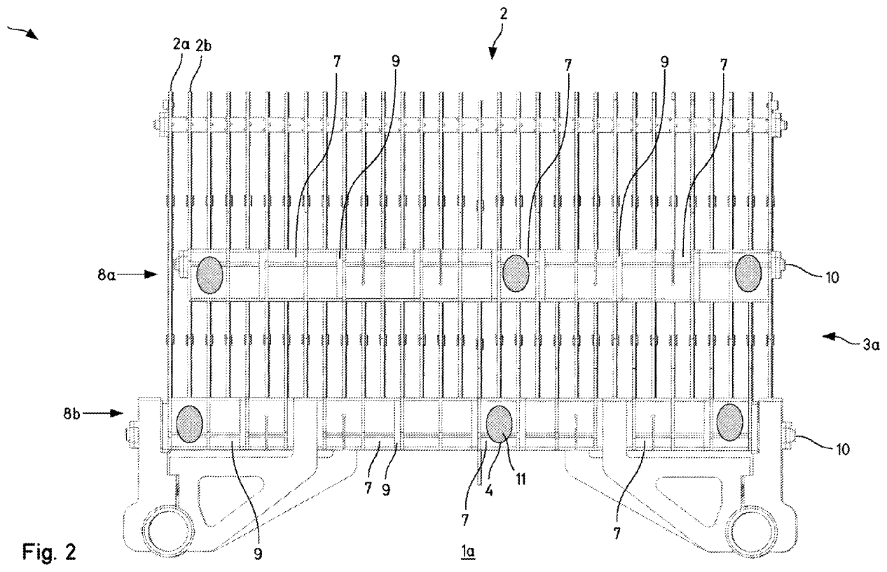

FIG. 2 shows a first end of the workpiece holder from FIG. 1;

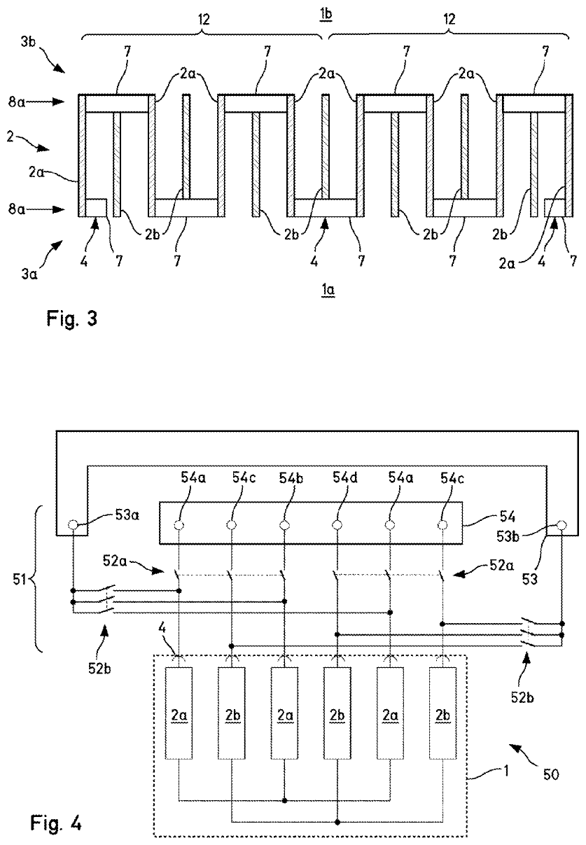

FIG. 3 shows an example of two circuits of a workpiece holder;

FIG. 4 shows an example of a system for plasma-enhanced chemical vapor deposition; and

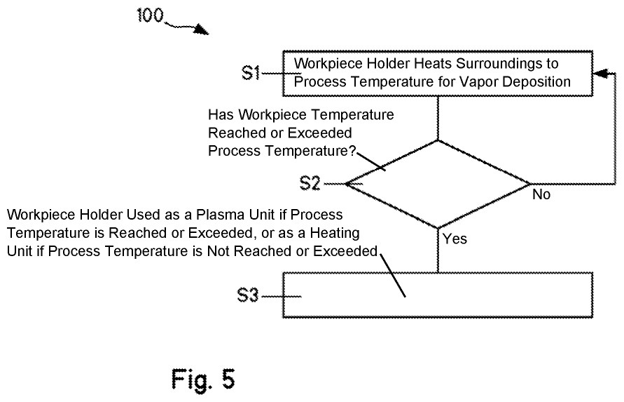

FIG. 5 shows an example of an operating method for a system for plasma-enhanced chemical vapor deposition.

FIG. 1 shows an example of a workpiece holder 1 for a system for plasma-enhanced chemical vapor deposition (PECVD), which is configured to generate a plasma from a process gas surrounding the workpiece holder and to heat the surroundings of the workpiece holder 1 to a process temperature provided for vapor deposition.

The workpiece holder 1 preferably has an electrode assembly 2, with the aid of which the plasma can be generated and the surroundings of the workpiece holder 1 can be heated. Since one component of the workpiece holder 1 therefore assumes two functions, corresponding components or assemblies can be omitted in a PECVD facility and the facility can therefore be implemented compactly and cost-effectively.

The electrode assembly 2 preferably comprises multiple electrodes 2a, 2b, of which only two are provided with a reference sign for reasons of clarity. The electrodes 2a, 2b are arranged in the example shown in parallel to one another and in a longitudinal direction L. In a first operating mode, in which the workpiece holder 1 is operated as a heating unit to heat the surroundings of the workpiece holder 1 to the process temperature, the electrodes 2a, 2b can be used as electric heating resistors. In a second operating mode, in which the workpiece holder 1 is operated as a plasma unit to generate the plasma from the process gas, the electrodes 2a, 2b can be used to generate electric fields, in particular high-frequency electric AC fields.

The electrode assembly 2 of the workpiece holder 1 is preferably configured to be connected to a current and/or voltage source via a first distributor assembly 3a. The first distributor assembly 3a can comprise, for example, a power connection, which expediently has at least four, in the present example six contact points 4 for electrically contacting the workpiece holder 1. The contact points 4 can be brought into contact, for example, upon insertion of the workpiece holder 1 into a process chamber of a PECVD facility, with contact pins also designated as current lances, which are arranged at a rear wall of the process chamber. For reasons of clarity, only one of the contact points 4 is provided with a reference sign.

The distribution of current provided or voltage provided via the contact points 4 at the electrode assembly 2 onto the electrodes 2a, 2b is expediently implemented with the aid of a second distributor assembly 3b. For this purpose, the first distributor assembly 3a can be arranged at a first end 1a of the workpiece holder 1 and the second distributor assembly 3b can be arranged at a second end 1b of the workpiece holder 1. The second end 1b is opposite to the first end 1a in the longitudinal direction L. This then also applies accordingly to the distributor assemblies 3a, 3b. Such an arrangement of the distributor assemblies 3a, 3b permits an interconnection of the electrode assembly 2 in such a way that adjacent electrodes are electrically isolated from one another and at the same time at least a part of the electrodes 2a, 2b, in particular at least two groups of electrodes 2a, 2b, are connected in series, as explained in more detail in conjunction with FIG. 3.

In particular, the electrodes 2a, 2b can be electrically interconnected with one another by the distributor assemblies 3a, 3b in such a way that all electrodes 2a, 2b of the workpiece holder 1 can be integrated into one or more heating circuits for conducting a low-frequency alternating current. At the same time, the electrodes 2a, 2b are also electrically interconnected with one another by the distributor assemblies 3a, 3b in such a way that all electrodes 2a, 2b of the workpiece holder 1 can be integrated in a plasma circuit for conducting a high-frequency alternating current.

For the insertion of the workpiece holder 1 into a process chamber of a PECVD facility, the workpiece holder 1 preferably has two running rails 5 aligned in the longitudinal direction L, which can run, for example, on corresponding rollers in the process chamber. In the present example, the running rails 5 are formed as tubes to save weight. The electrode assembly 2 is supported here by feet 6 on the running rails 5, wherein the feet 6 are electrically isolated from the electrodes 2a, 2b and are fastened on the running rails 5. In the present example, the feet 6 are fastened by clamping on the running rails 5, which can facilitate an exchange of the running rails 5.

FIG. 2 shows the first end 1a of the workpiece holder 1 from FIG. 1. The interconnection of the electrodes 2a, 2b of the electrode assembly 2 by the first distributor assembly 3a is recognizable therein.

The first distributor assembly 3a has multiple electrically conductive conducting elements 7 in the example shown, which extend in two rows 8a, 8b transversely to the longitudinal direction indicated in FIG. 1, namely preferably over the entire width of the workpiece holder 1, in particular of the electrode assembly 2. For reasons of clarity, only a few of the conducting elements 7 are provided with a reference sign.

In the example shown, electrodes 2a of a first group of conducting elements 7 from the upper row 8a are contacted, while electrodes 2b of a second group of conducting elements 7 from the lower row 8b are contacted. The electrodes 2a of the first group and the electrodes 2b of the second group are arranged alternately transversely to the longitudinal direction here (see FIG. 1). That is to say, one electrode 2a of the first group is always arranged adjacent to electrodes 2b of the second group and vice versa. In other words, the electrodes 2a of the first group, except for an edge electrode, are always arranged between two electrodes 2b of the second group and vice versa. Various circuits may thus be formed in the workpiece holder and the electrodes 2a, 2b can be used both for generating a plasma and also for heating workpiece holders depending on the energizing of the circuits or applied voltage.

Electrically insulating elements 9 are arranged between some conducting elements 7 to avoid a short-circuit of the circuits. For reasons of clarity, only a few of the insulating elements 9 are provided with a reference sign.

The conducting elements 7 can be formed, for example, as graphite blocks. The insulating elements 9 can be formed, for example, as ceramic plates. The conducting elements 7 and the insulating elements 9 each expediently have at least one fastening borehole (not shown) in the form of a passage, which is penetrated by at least one fastening means 10, preferably manufactured from insulating material, for fastening the first distributor assembly 3a. The fastening means 10 can be designed, for example, as a screw or threaded rod and, as shown by way of example in FIG. 2, can be secured with the aid of one or more nuts.

The contact points 4 of the power connection, which are preferably arranged at the first end 1a of the workpiece holder 1, are also well visible in FIG. 2. The contact points 4 can in particular be provided at conducting elements 7 of the first distributor assembly 3a. The contact points 4 preferably have conical boreholes 11, in which, for example, the contact pins in a process chamber can engage. In particular, the contact points 4 can be formed as conical boreholes 11 in conducting elements 7 of the first distributor assembly 3a. Not all contact points 4 and boreholes 11 are also provided with a reference sign here for reasons of clarity.

The second distributor assembly at the second end of the workpiece holder, which is not visible in FIG. 2, is preferably constructed corresponding to the first distributor assembly 3a. The second distributor assembly expediently also has conducting elements 7 and insulating elements 9, which are arranged in rows extending in parallel. The conducting elements 7 and insulating elements 9 can be arranged here in particular in such a way that they form the circuits described hereinafter in FIG. 3.

FIG. 3 shows an example of two circuits 12 of a workpiece holder, which has an electrode assembly 2 having multiple electrodes 2a, 2b and two distributor assemblies 3a, 3b, which are arranged at a first end 1a and a second end 1b, opposite to the first end, of the workpiece holder (see FIG. 1). Both circuits 12 are formed in this case at least from a first group of electrodes 2a and the distributor assemblies 3a, 3b of the workpiece holder. The electrodes 2a of the first group are electrically connected in series here via conducting elements 7 of the first and second distributor assemblies 3a, 3b.

Each of the circuits 12 extends from a contact point 4 of a power connection of the first distributor assembly 3a to another contact point 4 of the power connection. In the example shown here, the circuits 12 each extend from an outer contact point 4 to a middle contact point 4, wherein both circuits 12 share the middle contact point 4 here. The workpiece holder can be connected to at least one current and/or voltage source via the contact points 4.

The electrodes 2a of the first group are preferably each contacted by a conducting element 7 of the first distributor assembly 3a and a conducting element 7 of the second distributor assembly 3b. The conducting elements 7 of the first and second distributor assembly 3a, 3b contacting the electrodes 2a of the first group are arranged here in two upper rows 8a (see FIG. 2). Electric current provided at a contact point 4 thus flows meandering through the workpiece holder, in particular through the electrode assembly 2. In other words, provided electric current flows back and forth in each of the circuits 12 between the first end 1a and the second end 1b of the workpiece holder.

The electrodes 2b of a second group are preferably interconnected similarly to the electrodes 2a of the first group via conducting elements (not shown) of the first and second distributor assembly 3a, 3b, namely electrically in series. The conducting elements contacting the electrodes 2b of the second group can be arranged here in lower rows (see FIG. 2), so that the first and second group can be electrically contacted separately from one another. The electrodes 2b of the second group preferably form two further circuits (not shown) together with the two distributor assemblies 3a, 3b. Upon connection of a heating voltage source, for example an AC voltage source for providing low-frequency AC voltage, the electrodes 2a, 2b in the total of four circuits can be used as heating resistors. The circuits 12 therefore can also be referred to as heating circuits.

As shown in FIG. 3, the electrodes 2a of the first group and the electrodes 2b of the second group are arranged alternately adjacent to one another in the top view shown. When the electrodes 2a of the first group and the electrodes 2b of the second group are brought to different potentials at high frequency, high-frequency electric fields and thus also a plasma in a process gas surrounding the workpiece holder can be generated between the electrodes 2a, 2b. For this purpose, for example, a high-frequency AC voltage can be applied between the contact points 4, which are provided at conducting elements 7 of the first distributor assembly 3a from the upper row 9a, and contact points which are provided at conducting elements of the first distributor assembly from the lower row. The multiple (heating) circuits 12 can become part of a plasma circuit due to this contacting.

FIG. 4 shows an example of a system 50 for plasma-enhanced chemical vapor deposition. The system 50 has a switching device 51 having multiple switch assemblies 52a, 52b, a plasma voltage source 53 for providing high-frequency electric AC voltage, at least one heating voltage source 54 for providing low-frequency electric AC voltage, and a workpiece holder 1. The workpiece holder 1 is preferably configured both to generate a plasma from a process gas surrounding the workpiece holder 1 and to heat the surroundings of the workpiece holder 1 to a process temperature provided for vapor deposition. The system 50 expediently also has for this purpose a process chamber for receiving the workpiece holder 1, a gas feed system for introducing the process gas into the process chamber, and a gas discharge system for generating a vacuum in the process chamber. These last-mentioned components are not shown in FIG. 4 for reasons of clarity.

The system 50 is preferably designed in such a way that when the workpiece holder 1 is received in the process chamber, an electric connection is established between the plasma voltage source 53 or the at least one heating voltage source 54 and the workpiece holder 1, preferably via the switching device 51. The workpiece holder 1 can have a power connection having multiple contact points 4 for this purpose, for example, which can be contacted by contact pins arranged in the process chamber. For reasons of clarity, only one of the contact points 4 is provided with a reference sign.

The switching device 51 is preferably configured to initially electrically connect the at least one current source 54 to the workpiece holder 1 received by the process chamber, for example by closing a first switch assembly 52a. The switching device 51 can in particular be configured, by establishing this electric connection, to integrate the workpiece holder 1 into at least one heating circuit for conducting low-frequency alternating current.

The switching device 51 can be designed, for example, in such a way that upon closing of the first switch assembly 52a (i) low-frequency electric alternating current flows between two poles 54a, 54b of the at least one heating voltage source 54 through a first group of electrodes 2a of an electrode assembly of the workpiece holder 1 received by the process chamber and (ii) low-frequency electric alternating current flows between two further poles 54c, 54d of the at least one heating voltage source 54 through a second group of electrodes 2b of the electrode assembly. As can be seen well in FIG. 4, the electrodes 2a, 2b of a group are each electrically connected in series. In the present case four heating circuits are implemented using the interconnection shown in the example shown and in that two poles 54a and 54c are provided.

Since the electrodes 2a, 2b can act as heating resistors when the first switch assembly 52a is closed, the workpiece holder 1 is therefore operable in a first operating mode as a heating unit.

The switching device 51 is preferably furthermore configured to disconnect the heating voltage current source 54 from the workpiece holder 1 received by the process chamber and instead to electrically connect the plasma voltage source 53 to the workpiece holder 1, for example by opening the first switch assembly 52a and closing a second switch assembly 52b. The switching device 51 can in particular be configured, by establishing this electric connection, to integrate the workpiece holder 1 into a plasma circuit for conducting high-frequency alternating current.

The switching device 51 can be designed, for example, in such a way that upon closing of the second switch assembly 52b, a high-frequency electrical AC voltage is applied between the electrodes 2a of the first group and the electrodes 2b of the second group. For this purpose, the switching device 51 can be designed in particular in such a way that upon closing of the second switch assembly 52b, a first pole 53a of the plasma voltage source 53 is connectable to the electrodes 2a of the first group and a second pole 53b is connectable to the electrodes 2b of the second group.

Since the electrodes 2a of the first group and the electrodes 2b of the second group are arranged alternately as shown in FIG. 4 and can therefore generate high-frequency electric fields to generate a plasma when the second switch assembly 52b is closed, the workpiece holder 1 is therefore operable as a plasma unit in a second operating mode.

FIG. 5 shows an example of an operating method 100 for a system for plasma-enhanced chemical vapor deposition.

In a method step S1, a workpiece holder of the system is initially heated as a heating unit to heat the surroundings of the workpiece holder to a process temperature provided for vapor deposition. For this purpose, for example, a first switch assembly of a switching device can be closed in order to electrically connect at least one heating voltage source for providing a low-frequency AC voltage to the workpiece holder. In particular, the workpiece holder can thus be integrated in at least one heating circuit, so that low-frequency electric alternating current flows as heating current through multiple electrodes, connected in series in each circuit, of an electrode assembly of the workpiece holder.

In a further method step S2, it can be checked whether a temperature of the workpiece holder or its surroundings has reached or exceeded a predetermined process temperature. For this purpose, a temperature signal generated by a temperature sensor is expediently processed by a control unit of the switching device. In dependence on a result of the check, for example if the process temperature is reached or exceeded, in a further method step S3, the workpiece holder is preferably operated as a plasma unit for generating a plasma from a process gas surrounding the workpiece holder. If the process temperature is not (yet) reached or exceeded, the workpiece holder can be used further in method step S1 as a heating unit.

In method step S3, for example, the first switch assembly can be opened and a second switch assembly of the switching device can be closed in order to disconnect the at least one heating voltage source from the workpiece holder and instead to electrically connect a plasma voltage source to the workpiece holder to provide a high-frequency AC voltage. In particular, the workpiece holder can thus be integrated into a plasma circuit, so that the high-frequency AC voltage for generating a plasma is applied between two electrode groups.

### LIST OF REFERENCE SIGNS

1 workpiece holder
1a, 2b end
2 electrode assembly
2a, 2b electrode
3a, 3b distributor assembly
4 contact point
5 running rail
6 foot
7 conducting element
8a, 8b row
9 insulating element
10 fastening means
11 borehole
12 circuit
50 system
51 switching device
52a, 52b switch assembly
53 plasma voltage source
53a, b pole
54 heating voltage source
54a-d pole
100 operating method
S1-S3 method step

1-15. (canceled)

16. A workpiece holder for a system for plasma-enhanced chemical vapor deposition,
the workpiece holder configured to generate a plasma from a process gas surrounding the workpiece holder; and
the workpiece holder configured to heat surroundings of the workpiece holder to a process temperature provided for vapor deposition.

17. The workpiece holder according to claim 16, wherein the workpiece holder is configured to conduct electric heating current.

18. The workpiece holder according to claim 16, wherein the workpiece holder is configured to conduct electric alternating current in multiple circuits.

19. The workpiece holder according to claim 16, which further comprises a plurality of electrodes disposed in parallel and operating as electric heating resistors.

20. The workpiece holder according to claim 19, wherein said plurality of electrodes include at least a part of said plurality of electrodes being electrically connected in series.

21. The workpiece holder according to claim 19, wherein said plurality of electrodes include adjacent electrodes being electrically isolated from one another.

22. The workpiece holder according to claim 16, which further comprises:
first and second mutually opposite ends of the workpiece holder;
a first distributor assembly disposed at said first end of the workpiece holder; and
a second distributor assembly disposed at said second end of the workpiece holder;
said first and second distributor assemblies configured to distribute low-frequency and high-frequency electric AC voltage to heat the surroundings of the workpiece holder or to generate the plasma.

23. The workpiece holder according to claim 22, which further comprises a plurality of parallel electrodes, at least one of said distributor assemblies electrically conductively connecting at least a part of said plurality of electrodes to one another.

24. The workpiece holder according to claim 16, which further comprises a power connection having at least four spatially separated contact points for electrically contacting the workpiece holder.

25. The workpiece holder according to claim 24, wherein said contact points have conical boreholes for receiving contact pins.

26. A system for plasma-enhanced chemical vapor deposition, the system comprising:
a workpiece holder according to claim 16; and
a process chamber configured to be charged with at least one process gas, said process chamber configured for receiving the workpiece holder.

27. The system according to claim 26, which further comprises:
a switching device;
said switching device configured to act as a heating unit to initially operate the workpiece holder to heat the surroundings of the workpiece holder to a process temperature provided for vapor deposition, and
said switching device configured to act as a plasma unit to then generate a plasma from a process gas surrounding the workpiece holder.

28. The system according to claim 27, which further comprises:
a plasma voltage source for providing high-frequency electric AC voltage for operating the workpiece holder as a plasma unit; and
at least one heating voltage source for providing low-frequency electric AC voltage for operating the workpiece holder as a heating unit;
said switching device configured, after heating the surroundings of the workpiece holder to the process temperature, to disconnect said at least one heating voltage source from the workpiece holder and to connect said plasma voltage source to the workpiece holder.

29. The system according to claim 26, wherein said switching device is configured to integrate the workpiece holder:
during operation as a plasma unit in a single circuit, and
during operation as a heating unit in at least two parallel circuits.

30. An operating method for a system for plasma-enhanced chemical vapor deposition, the method comprising:
initially operating a workpiece holder as a heating unit to heat surroundings of the workpiece holder to a process temperature provided for vapor deposition; and
then operating the workpiece holder as a plasma unit to generate a plasma from a process gas surrounding the workpiece holder.
